(19) United States
(12) Patent Application Publication
(10) Pub. No.: US 2026/0170215 A1
(43) Pub. Date: Jun. 18, 2026

(54) LEARNING LIBRARY CELL REPRESENTATIONS IN VECTOR SPACE

(71) Applicant: NVIDIA Corporation, Santa Clara, CA (US)

(72) Inventors: Rongjian Liang, Austin, TX (US); Haoxing Ren, Austin, TX (US)

(21) Appl. No.: 19/325,345

(22) Filed: Sep. 10, 2025

Related U.S. Application Data
(60) Provisional application No. 63/735,251, filed on Dec. 17, 2024.

(51) Int. Cl. G06F 30/333

(52) U.S. Cl. CPC G06F 30/333

(57) ABSTRACT

In Very Large Scale Integration (VLSI) design, representations of library cells, which are generally comprised of functional, electrical, and physical properties, are vital for effective machine learning (ML)-based circuit analysis and optimization, as library cells are the fundamental building blocks of circuit netlists. Traditional methods often rely on manually defined features, requiring extensive expertise and feature engineering, whereas one-hot encoding methods demand large amounts of domain-specific training data, which may not always be available. The present disclosure provides a self-supervised learning approach to generate library cell representations, including for example the learning of functional and electrical representations of library cells in a vector space which are compatible with diverse machine learning architectures, including transformers.

### CLAIM OF PRIORITY

This application claims the benefit of U.S. Provisional Application No. 63/735,251 (Attorney Docket No. NVIDP1430+/24-AU-1604US01) titled “LEARNING LIBRARY CELL REPRESENTATIONS IN VECTOR SPACE,” filed Dec. 17, 2024, the entire contents of which is incorporated herein by reference.

### TECHNICAL FIELD

The present disclosure relates to generation of library cell representations for machine-learning based circuit analysis and optimization.

### BACKGROUND

In Very Large Scale Integration (VLSI) design, library cells have three categories of properties: functional, electrical, and physical. Functional properties define a cell's logical behavior, determining how it performs logic functions. Electrical properties capture timing, power, and signal integrity, including parameters like propagation delay, transition time, capacitance, leakage and internal power, and noise margins. Physical properties describe a cell's layout and geometry, such as cell dimensions and pin locations. These properties can be classified as static or dynamic. Static properties, like physical characteristics, remain constant, while dynamic properties, such as most functional and electrical behaviors, vary with input conditions.

Library cell representations are vital for effective machine learning (ML)-based circuit analysis and optimization, as library cells are the fundamental building blocks of circuit netlists. Traditional methods often rely on manually defined features, requiring extensive expertise and feature engineering. Alternatively, one-hot encoding demands large amounts of domain-specific training data, which may not always be available.

While some efforts have introduced pre-training methods that achieve notable results in circuit representation, they primarily focus on structural and functional aspects of AND-Inverter graphs, overlooking other cell types and electrical properties. Moreover, they embed circuit knowledge within the weights of graph neural networks, restricting the transferability of this knowledge to other machine learning models. Another related research direction focuses on machine learning-based library cell characterization. While these methods have shown promise, they primarily aim to improve arc-based timing characterization accuracy rather than enabling machine learning models to capture and understand semantic relationships among cells.

There is thus a need for addressing these issues and/or other issues associated with the prior art. For example, there is a need for a self-supervised learning approach to generate library cell representations, including for example the learning of functional and electrical representations of library cells in a vector space which are compatible with diverse machine learning architectures, including transformers.

### SUMMARY

A method, computer readable medium, and system are disclosed for generating a representation of a library cell of a circuit design. A vector space representation of a library cell of a circuit design is learned. The vector space representation of the library cell is output.

### BRIEF DESCRIPTION OF THE DRAWINGS

FIG. 1 illustrates a flowchart of a method for generating a representation of a library cell of a circuit design, in accordance with an embodiment.

FIG. 2 illustrates an attention-based machine learning model architecture for generation of library cell representations, in accordance with an embodiment.

FIG. 3A illustrates regularity tests for use by the attention-based machine learning model architecture of FIG. 2, in accordance with an embodiment.

FIG. 3B illustrates self-supervised training data generation for use by the attention-based machine learning model architecture of FIG. 2, in accordance with an embodiment.

FIG. 4 illustrates a method for using library cell representations in a downstream application, in accordance with an embodiment.

FIG. 5A illustrates inference and/or training logic, according to at least one embodiment.

FIG. 5B illustrates inference and/or training logic, according to at least one embodiment.

FIG. 6 illustrates training and deployment of a neural network, according to at least one embodiment.

FIG. 7 illustrates an example data center system, according to at least one embodiment.

### DETAILED DESCRIPTION

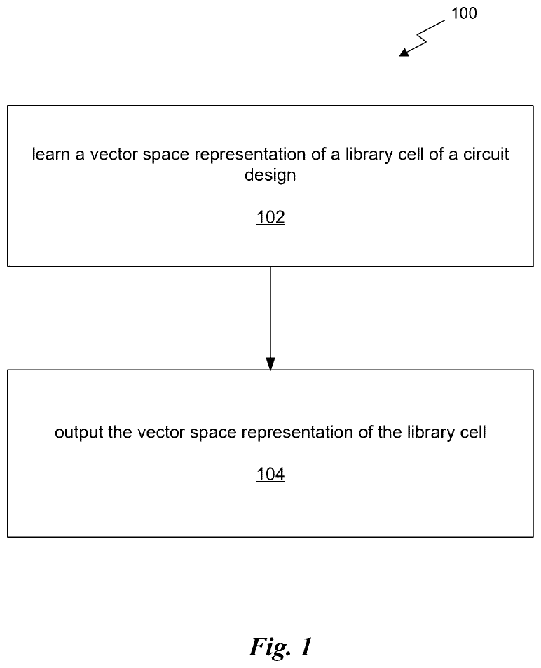

FIG. 1 illustrates a flowchart of a method 100 for generating a representation of a library cell of a circuit design, in accordance with an embodiment. The method 100 may be performed by a device, which may be comprised of a processing unit, a program, custom circuitry, or a combination thereof, in an embodiment. In another embodiment, a system comprised of a non-transitory memory storage comprising instructions, and one or more processors in communication with the memory, may execute the instructions to perform the method 100. In another embodiment, a non-transitory computer-readable media may store computer instructions which when executed by one or more processors of a device cause the device to perform the method 100.

In operation 102, a vector space representation of a library cell of a circuit design is learned. The circuit design refers to a design of an integrated circuit that is comprised of a plurality of library cells. In an embodiment, the circuit design may be preconfigured, for example using a circuit design application (e.g. electronic design automation (EDA) tool). In an embodiment, the circuit design may be defined in one or more electronic files, each of which may be a text-based file such as a Liberty file.

As mentioned, the circuit design is comprised of a plurality of library cells. For example, the circuit design may define a circuit that is comprised of the plurality of library cells. A library cell is a component of a circuit and is defined by one or more properties (e.g. characteristics). Each of the library cells may be defined in the one or more electronic files. For example, the properties of the library cell may be predefined in a set of text-based files.

In an embodiment, the library cell may include one or more functional properties. A functional property may define logical behavior of the library cell, determining how it performs logic functions. In an embodiment, the library cell may include one or more electrical properties. An electrical property may define timing, power, and signal integrity, including parameters like propagation delay, transition time, capacitance, leakage and internal power, and noise margins. In an embodiment, the library cell may include one or more physical properties. A physical property may define a layout and geometry of the library cell, such as cell dimensions and pin locations. In an embodiment, the properties of a library cell may include dynamic and/or static properties. For example, static properties, such as physical characteristics, remain constant, while dynamic properties, such as most functional and electrical behaviors, may vary with input conditions.

The vector space representation of the library cell (that is learned) refers to a representation of the library cell that is generated in vector space. In an embodiment, the vector space representation may be learned to encode properties of the library cell. In an embodiment, the properties that are encoded may be the dynamic properties of the library cell, such as the functional characteristics of the library cell and electrical characteristics of the library cell.

In an embodiment, the vector space representation of the library cell may be learned such that the vector space representation maximizes accuracy on one or more preconfigured regularity tests. In an embodiment, the one or more preconfigured regularity tests may include at least one inverting functionality test that evaluates whether the vector space representation captures an inverting functionality relationship existing in the circuit design. In an embodiment, the one or more preconfigured regularity tests may include at least one functional similarity test that evaluates whether the vector space representation captures a functional similarity existing in the circuit design. In an embodiment, the one or more preconfigured regularity tests may include at least one electrical similarity test that evaluates whether the vector space representation captures a delay-specific similarity relationship existing in the circuit design.

In an embodiment, the vector space representation may be learned using an attention-based machine learning model architecture. In an embodiment, the attention-based machine learning model architecture may include one or more components trained with self-supervision using a set of files describing functional and electrical properties of library cells. For example, in an embodiment, the attention-based machine learning model architecture may include a first model that learns a functional output prediction for the vector space representation a second model that learns an electrical output prediction for the vector space representation. In an embodiment, the functional output prediction may be learned by: generating a functional embedding for an output pin by attending to a functional embedding of the library cell and embeddings of all corresponding pins, and transforming the functional embedding of the output pin into a logic value prediction representing the functional output prediction. In an embodiment, the electrical prediction may be learned by: concatenating a base electrical embedding of the library cell with a property token embedding to form a concatenated embedding, combining the concatenated embedding with input and output pin embeddings to create a timing arc embedding, and mapping the timing arc embedding to the electrical output prediction.

While operation 102 mentions that a vector space representation of a library cell of the circuit design is learned, it should be noted that this may refer to learning vector space representations of one or more library cells of the circuit design. Thus, in an embodiment, operation 102 may include learning vector space representations of a plurality of library cells of the circuit design, such as learning vector space representations of all library cells of the circuit design or a subset of all library cells of the circuit design.

In operation 104, the vector space representation of the library cell is output. In an embodiment, the vector space representation of the library cell may be output to a computer memory. In an embodiment, the vector space representation of the library cell may be output to a downstream application. In an embodiment, the downstream application may include a machine learning model that is configured to process the vector space representation of the library cell to generate a prediction for the library cell and/or for the circuit design. In an embodiment, the method 100 may further include the processing of the vector space representation of the library cell by the downstream application.

In an embodiment, the downstream application may include a machine learning model that optimizes the circuit design based on the vector space representation of the library cell. In an embodiment, the downstream application may include a machine learning model that predicts an output vector at an output pin of the library cell using the vector space representation of the library cell. In an embodiment, the downstream application may include a machine learning model that predicts a logic probability for an output of the library cell using the vector space representation of the library cell. In an embodiment, the downstream application may include a machine learning model that predicts switching activity of the library cell using the vector space representation of the library cell.

To this end, the method 100 may be performed to learn a library cell representation in a vector space, including for example learning to encode functional and electrical properties of the library cell. In an embodiment, the vector space representation may be compatible with diverse machine learning architectures, including transformers, to perform various downstream tasks as desired, such as circuit design optimization for example.

Exemplary implementation of the method 100 for optimizing a circuit design

As noted above, in an embodiment, the method 100 may be carried out to optimize a circuit design using vector space representations of library cells in the circuit design. In this embodiment, the method 100 may be implemented to: access an preconfigured circuit design comprised of a plurality of library cells; learn a vector space representation of one or more library cells of the plurality of library cells, the vector space representation for each library cell of the one or more library cells being a learned encoding of dynamic properties of the library cell; and process the vector space representation of the one or more library cells, by a machine learning model, to generate a new circuit design that is more optimal than the preconfigured circuit design.

Further embodiments will now be provided in the description of the subsequent figures. It should be noted that the embodiments disclosed herein with reference to the method 100 of FIG. 1 may apply to and/or be used in combination with any of the embodiments of the remaining figures below.

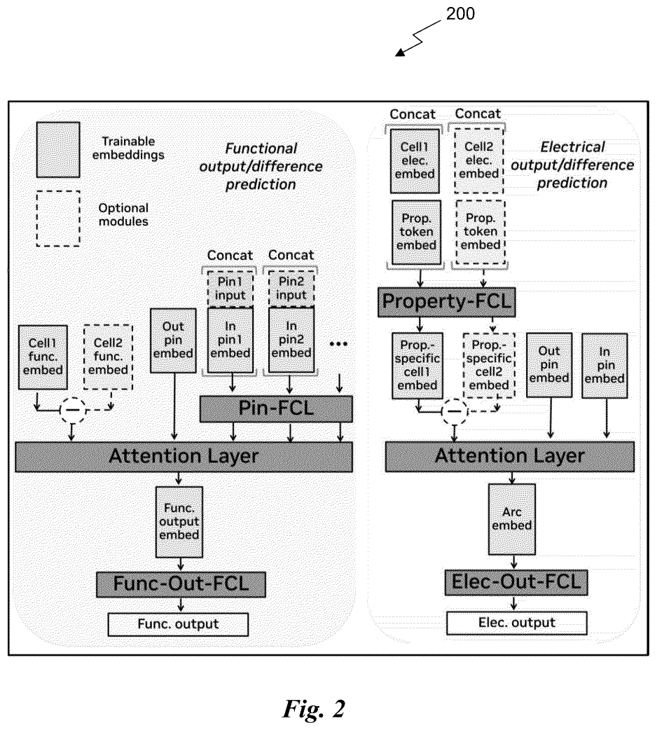

FIG. 2 illustrates an attention-based machine learning model architecture 200 for generation of library cell representations, in accordance with an embodiment. The architecture 200 may be implemented to carry out the method 100 of FIG. 1. Thus, the definitions and descriptions provided above may equally apply to the present embodiment.

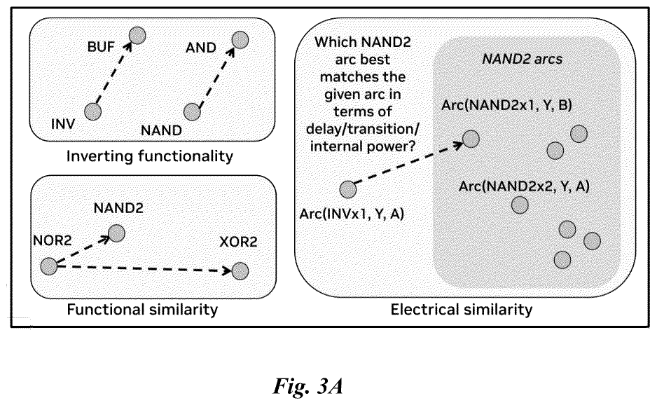

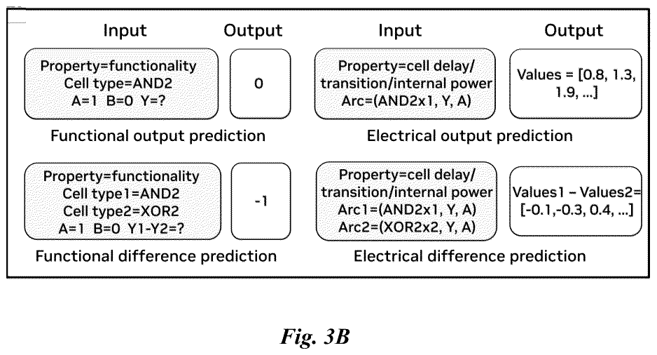

The attention-based machine learning model architecture 200, as described herein, is configured to learn library cell representations for a given circuit design. Initially, regularity tests may be generated for use in evaluating the learned library cell representations, as depicted in FIG. 3A. The generation of the regularity tests is based on the library cell's semantics being fully characterized by its responses to specific inputs. Functional and electrical similarities between library cells can thus be defined by differences in output responses under identical input conditions. Such similarities are crucial for machine learning models to analyze and optimize circuit netlist performance while enabling effective cross-cell knowledge transfer. Beyond similarity, functional inversion is another key relationship for tasks like logic propagation and netlist rewriting.

Based on these observations, three sets of regularity tests are automatically derived from Liberty files. The cell representation learning problem can then be formulated as learning vector space representations that maximize accuracy on these regularity tests. This approach assumes well-documented Liberty files with consistent pin naming. Consequently, input pin reordering is not considered in the regularity tests.

Liberty files refer to a standard format used to describe the functional and electrical properties of library cells (also referred to herein as “cells”). It should be noted that other embodiments are also contemplated in which file formats other than Liberty files, which likewise describe the functional and electrical properties of library cells, may be similarly used in the context of the present embodiments. In a Liberty file, a library cell's function may be described by its functional expression; for instance, the function expression for AND2x2 ASAP7 75t R is A*B.

In one embodiment of a library that may be used in the context of the attention-based machine learning model architecture 200, cell propagation delay, transition time, and internal power may be characterized as functions of input transition time and total output capacitance, represented through lookup tables. In other embodiments, the attention-based machine learning model architecture 200 may be adaptable to more advanced delay and power models, as long as the output responses of a cell can be efficiently sampled.

Details of the regularity tests are elaborated as follows.

### A. Inverting Functionality Tests

This test set evaluates inverting functionality relationships among cell types. A cell type refers to a group of standard cells with the same functionality but differing in driving strengths, voltage thresholds, or layout implementations. Two cell types with identical input pin names are considered to have an inverting functionality relationship if their outputs always complement each other, such as BUF (buffer) and INV (inverter).

After identifying all inverting functionality pairs, tests are designed to evaluate these relationships. For instance, as shown in FIG. 3A, given two pairs, (BUF, INV) and (AND2, NAND2), two tests are created:

$$( BUF vs . INV ) = ( AND 2 vs . ? )$$

$$( AND 2 vs . NAND 2 ) = ( BUF vs . ? )$$

More examples can be found in Table 1.

TABLE 1

| Relationship | | Question | Answer | Evaluation metrics |
|---|---|---|---|---|
| Inverting | | (BUF vs. INV) = (AND2 vs. ?) | NAND2 | Use linear algebraic operations |
| functionality | | (BUF vs. INV) = (XNOR2 vs. ?) | XOR2 | on cell vectors to determine |
| | | (AO211 vs. AOI211) = (OR2 vs. ?) | NOR2 | the answer. E.g., assess |
| | | (OR5 vs. NOR5) = (OA333 vs. ?) | OAI333 | whether vector(NAND2) falls |
| | | (MAJ vs. MAJI) = (AND5 vs. ?) | NAND5 | within the top-K closest vectors |
| | | | | to vector(INV) − vector(BUF) + |
| | | | | vector(AND2), and report |
| | | | | the resulting top-K accuracy |
| Functional | Easy | Which is closer to AO21: | OA21 | Determine the answer by |
| similarity | | OA21 or AOI21? | | evaluating the Euclidean |
| | | Which is closer to NAND5: | OR5 | distance between functional |
| | | OR5 or NOR5? | | cell vectors, and report the |
| | | Which is closer to NOR4: | AND4 | accuracy of the binary |
| | | AND4 or NAND4? | | classification |
| | Hard | Which is closer to A2O1A1I: | O2A1O1I | |
| | | O2A1O1I or AO211? | | |
| | | Which is closer to A2O1A1I: | OAI211 | |
| | | OAI211 or AOI211? | | |
| | | Which is closer to NOR2: | NAND2 | |
| | | NAND2 or XOR2? | | |
| Electrical | Rise | Which NOR2 arc is closest to | arc(NOR2x1, | Determine the answer by |
| similarity | delay | arc(INVx1, Y, A) | Y, B) | evaluating the Euclidean |
| | | Which NAND2 arc is closest to | arc(NAND2xp33, | distance between |
| | | arc(INVxp33, Y, A) | Y, B) | delay/transition/power-specific |
| | Fall | Which NOR2 arc is closest to | arc(NOR2xp67, | cell arc vectors and report |
| | delay | arc(A2O1A1Ixp33, Y, A1) | Y, A) | top-K accuracy |
| | | Which BUF arc is closest to | arc(BUFx8, | |
| | | arc(AO211x2, Y, A1) | Y, A) | |
| | Rise | Which NAND2 arc is closest to | arc(NAND2x1, | |
| | transition | arc(INVx1, Y, A) | Y, B) | |
| | | Which NAND2 arc is closest to | arc(NAND2x2, | |
| | | arc(INVx2, Y, A) | Y, B) | |
| | Fall | Which BUF arc is closest to | arc(BUFx2, | |
| | transition | arc(AO211x2, Y, A1) | Y, A) | |
| | | Which BUF ar is closest to | arc(BUFx4, | |
| | | arc(AO211x2, Y, A2) | Y, A) | |
| | Rise | Which NOR2 arc is closest to | arc(NOR2x1, | |
| | internal | arc(INVx1, Y, A) | Y, A) | |
| | power | Which NOR2 arc is closest to | arc(NOR2x2, | |
| | | arc(INVx2, Y, A) | Y, A) | |
| | Fall | Which BUF arc is closest to | arc(BUFx2, | |
| | internal | arc(AO211x2, Y, A1) | Y, A) | |
| | power | Which BUF arc is closest to | arc(BUFx2, | |
| | | arc(AO211x2, Y, A2) | Y, A) | |

Using linear algebraic operations on cell vectors, it is assessed whether the inferred vector (e.g., vector (NAND2)) ranks among the top-K closest vectors to the computed vector (e.g., vector(INV)−vector(BUF)+vector(AND2)). The resulting top-K accuracy indicates how well the learned cell representations capture inverting functionality relationships.

### B. Functional Similarity Tests

This test set evaluates functional similarity among cell types with identical input pins. To simplify the analysis, single output cells are the focus of the present description, which may constitute the majority in the given library. Other embodiments are contemplated extend functional similarity evaluation to individual output pins.

Functional similarity between two cells is computed by comparing their truth tables, as shown in Table 2. It is defined as the ratio of matching output values to the total number of input combinations.

TABLE 2

| A | B | Y (NAND2) | Y(XOR2) | Y (NOR2) |
|---|---|---|---|---|
| 0 | 0 | 1 | 0 | 0 |
| 0 | 1 | 1 | 1 | 0 |
| 1 | 0 | 1 | 1 | 0 |
| 1 | 1 | 0 | 0 | 0 |

For example, the functional similarity between NAND2 and NOR2 is FunSim(NAND2, NOR2)=2/4, while FunSim(XOR2,NOR2)=¼. A functional similarity test is created as:

Which is closer to NOR2: NAND2 or XOR2? And the answer is NAND2 as FunSim(NAND2, NOR2)>FunSim(XOR2,NOR2).

Functional similarity tests (e.g., which is closer to C: A or B?) are further categorized based on the similarity difference:
Easy test if 0.5≤|FunSim(B,C)−FunSim(A,C)|, the difference is substantial, making the test easier;
Hard test if 0<FunSim(B,C)−FunSim(A,C)|<0.5, the similarity scores are closer, making the test more challenging.

These tests are answered by comparing the Euclidean distances between functional cell vectors. As binary classification tasks, random guessing yields an accuracy of 50%. Higher accuracy indicates that the learned representations effectively capture functional similarity.

### C. Electrical Similarity Tests

This test set evaluates electrical similarity among cell arcs, encompassing rise/fall delay, transition time and internal power. The following description details the process of deriving electrical similarity tests using rise delay as an example, which consists of the following 4 steps:
(1) Input condition sampling: The Non-Linear Delay Model in the library represents delays using lookup tables parameterized by input slew and output load. To construct input condition combinations, we first determine the maximal ranges of input slew and output load across all cells. After applying a logarithmic transformation to these ranges, we uniformly sample 150 points from each range. This results in 150×150=22, 500 input condition combinations, denoted as conditions=[(slew1, load1), (slew2, load2), . . . ].
(2) Output value calculation: The identical input conditions are applied to all cell arcs and the rise delay values are computed. These delay values are then logarithmically transformed to ensure that the distribution approximates a Gaussian distribution, producing a set of transformed delays log-delay=[log(delay)1, log(delay)2, . . . ].
(3) Similarity measurement. Euclidean distance is used to measure the similarity between log-delay vectors of two arcs.
(4) Similarity test creation and evaluation metrics. One example test is: “Which NOR2 arc is closest to arc (INVx1, Y,A) in terms of rise cell delay?” To answer this, the distance between the rise delay-specific representation of arc (INVx1,Y,A) and all arcs in NOR2 cells is computed, then the NOR2 arc with the smallest distance is reported. The top-K accuracy measures how effectively the learned cell representations capture delay-specific similarity relationships.

It is important to note that the test sets described above are not exhaustive in defining what can be captured. They are designed for fast evaluation of the quality of cell representations, but they do not constrain the scope of what can be learned. For instance, functional similarities between cells may be identified, despite their differing input configurations.

Returning to the attention-based machine learning model architecture 200, the library cell representations may be learned using training data. In an embodiment, the training data may be generated as self-supervised training data, per the depiction in FIG. 3B.

An automatic method is used to create comprehensive functional and electrical data from Liberty files, removing the need for costly labeling.

In natural language processing, masked prediction—predicting missing words based on context—has proven effective for generating word representations, as a word's semantics are defined by its context. Inspired by this, self-supervised learning methods tailored to capture the semantics of cells may be used. Since a cell's semantics are determined by its response to input conditions, four self-supervised tasks are introduced, where training data is derived from the functional and electrical responses of cells, as depicted in FIG. 3B.
(1) Functional output prediction: It predicts the output logic value of a cell given its input logic values. Example: For an AND2 cell, with inputs A=1 and B=0, the output Y is? (answer: 0).
(2) Functional difference prediction: It predicts the output logic value difference between two cells given the same input logic values. Example: For cells AND2 and XOR2, with inputs A=1 and B=0, the difference Y(AND2)−Y(XOR2) is? (answer: −1).
(3) Electrical output prediction: it predicts the electrical property values (e.g., delay, power, transition) of a specific cell arc under the input conditions introduced above with respect to the Electrical Similarity Tests. Example: For the arc (AND2x1,Y,A), the rise cell delay is? (answer: [0.8, 1.3, 1.4, . . . ]).
(4) Electrical difference prediction: It predicts the difference in electrical property values between two cell arcs under the same conditions. Example: For arc (AND2x1,Y,A) and arc (XOR2x2, Y,A), the rise cell delay difference is? (answer: [−0.1,−0.3, 0.2, . . . ]).

Difference prediction data emphasizes how cells differ in functionality or electrical properties, complementing to the absolute output value prediction. These tests ensure the model captures subtle relationships between cells, improving robustness and aligning with real-world design tasks that rely on comparing cell behaviors.

Returning again to attention-based machine learning model architecture 200, the architecture 200 is designed to efficiently process functional and electrical datasets introduced above. The architecture 200 ensures consistent-length vector representations for cells with different input/output configurations, while also supporting property-specific representations for both entire cells and individual timing arcs.

Since a cell's functional properties are independent of its electrical properties, two separate models are included to learn functional and electrical representations. Despite being distinct, the two models share a similar architecture, as shown in FIG. 2. The architecture 200 includes learnable representations (embeddings) for cells, pin names, and properties (e.g., rise delay). For functional output prediction, the attention layer generates the functional embedding for an output pin by attending to the cell's functional embedding and the embeddings of all corresponding pins. This attention mechanism allows the model to accommodate cells with varying pin counts. Multiple fully connected layers, referred to as Func-Out-FCL in FIG. 2, then transform the functional embedding of the output pin into a logic value prediction.

For electrical output prediction, an electrical property-specific (e.g., rise delay) cell representation is created by concatenating the base electrical embedding of the cell with the property token embedding and passing them through the fully connected layer Property-FCL. Since the same input conditions are applied to all arcs, the input conditions are not taken as input. An attention layer then combines the property-specific cell embedding with the input and output pin embeddings to create the timing arc embedding. The Elec-Out-FCL further maps this arc embedding to the electrical output prediction.

For functional and electrical difference prediction tasks, the model includes an additional branch to compute the embeddings and differences between two cells, as depicted by the optional modules in FIG. 2. This architecture offers flexibility to adapt to various learning tasks while maintaining consistency across diverse prediction objectives.

To encourage the models to encode cell knowledge within the cell embeddings rather than the weights of the attention and fully connected layers, the number of learnable parameters in these layers is restricted. Specifically, a single-head attention operator is used in the Attention Layer module and two-layer fully connected operators are used in the FCL modules.

Integrating the architecture 200 with a machine learning model configured to process the library cell representations

Two embodiments for integrating the architecture 200 into machine learning models for downstream applications include:
(1) Representation-based integration: Directly use pre-trained cell embeddings or property-specific cell/arc representations as input features for downstream tasks. This approach is simple and compatible with a wide range of machine learning models.
(2) Model-based integration: Incorporate the architecture 200 into downstream machine learning models for circuit applications. By using the architecture's 200 self-supervised training as a pretraining step, both cell embeddings and model weights are initialized effectively. This tightly integrates architecture 200 with the downstream task, potentially yielding greater performance benefits compared to the first embodiment.

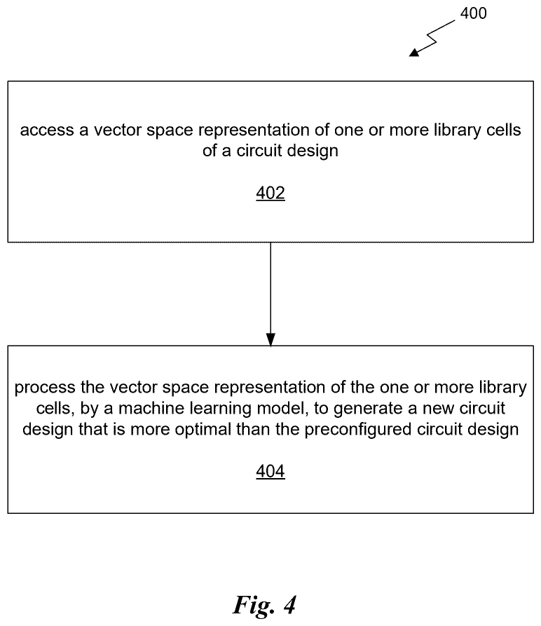

FIG. 4 illustrates a method 400 for using library cell representations in a downstream application, in accordance with an embodiment. In the context of the present embodiment, the library cell representations may be those generated per the method 100 of FIG. 1 and/or per the architecture 200 of FIG. 2.

In operation 402, a vector space representation of one or more library cells of a (initial) circuit design are accessed. Again, the vector space representation(s) may be generated per the method 100 of FIG. 1 and/or per the architecture 200 of FIG. 2.

In operation 404, the vector space representation of the one or more library cells is/are processed, by a machine learning model, to generate a new circuit design that is more optimal than the preconfigured circuit design. A more optimal circuit design refers to a circuit design that improves on one or more metrics when compared to another circuit design (e.g. the preconfigured circuit design). The metrics may include performance, efficiency, cost, reliability, etc. The machine learning model refers to a model training using machine learning to optimize one or more features of a circuit design given the vector space representation of the one or more library cells of the circuit design. Thus, operation 404 may generate a new circuit design that is more optimal than the initial circuit design.

In an embodiment, the machine learning model can be formulated as a generative artificial intelligence (AI) system that takes as input a pre-optimized netlist, where each cell is encoded as a learned vector-space representation, and generates an optimized netlist as output. Typical optimization tasks performed by the model may include gate sizing and buffering. In an embodiment, the model may be trained on paired examples of pre-optimized netlist and optimized netlist, enabling it to learn the transformation patterns that drive effective circuit optimization.

In an embodiment, the new circuit design may be used as the basis for fabricating a physical circuit. For example, a fabrication system may create the circuit per the specifications in the new circuit design.

### Machine Learning

Deep neural networks (DNNs), including deep learning models, developed on processors have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions. Inferencing is less compute-intensive than training, being a latency-sensitive process where a trained neural network is applied to new inputs it has not seen before to classify images, translate speech, and generally infer new information.

### Inference and Training Logic

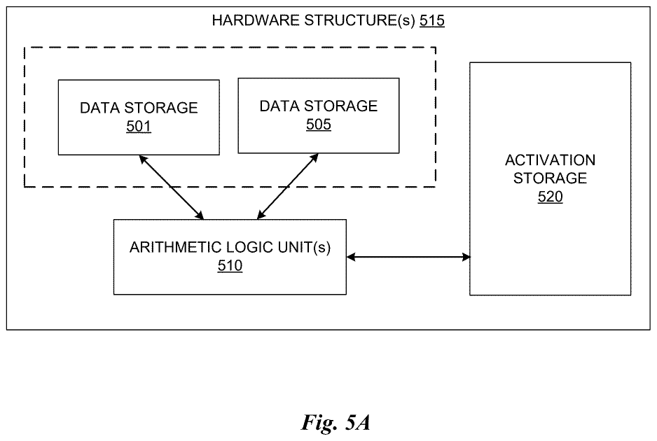

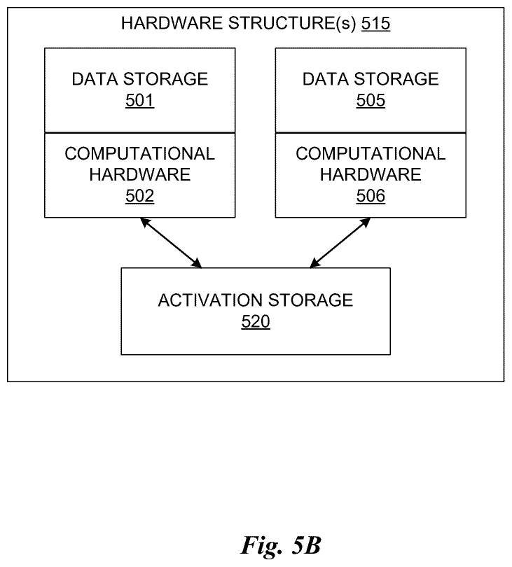

As noted above, a deep learning or neural learning system needs to be trained to generate inferences from input data. Details regarding inference and/or training logic 515 for a deep learning or neural learning system are provided below in conjunction with FIGS. 5A and/or 5B.

In at least one embodiment, inference and/or training logic 515 may include, without limitation, a data storage 501 to store forward and/or output weight and/or input/output data corresponding to neurons or layers of a neural network trained and/or used for inferencing in aspects of one or more embodiments. In at least one embodiment data storage 501 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of data storage 501 may be included with other on-chip or off-chip data storage, including a processor's L1, L2, or L3 cache or system memory.

In at least one embodiment, any portion of data storage 501 may be internal or external to one or more processors or other hardware logic devices or circuits. In at least one embodiment, data storage 501 may be cache memory, dynamic randomly addressable memory (“DRAM”), static randomly addressable memory (“SRAM”), non-volatile memory (e.g., Flash memory), or other storage. In at least one embodiment, choice of whether data storage 501 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 515 may include, without limitation, a data storage 505 to store backward and/or output weight and/or input/output data corresponding to neurons or layers of a neural network trained and/or used for inferencing in aspects of one or more embodiments. In at least one embodiment, data storage 505 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, any portion of data storage 505 may be included with other on-chip or off-chip data storage, including a processor's L1, L2, or L3 cache or system memory. In at least one embodiment, any portion of data storage 505 may be internal or external to on one or more processors or other hardware logic devices or circuits. In at least one embodiment, data storage 505 may be cache memory, DRAM, SRAM, non-volatile memory (e.g., Flash memory), or other storage. In at least one embodiment, choice of whether data storage 505 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, data storage 501 and data storage 505 may be separate storage structures. In at least one embodiment, data storage 501 and data storage 505 may be same storage structure. In at least one embodiment, data storage 501 and data storage 505 may be partially same storage structure and partially separate storage structures. In at least one embodiment, any portion of data storage 501 and data storage 505 may be included with other on-chip or off-chip data storage, including a processor's L1, L2, or L3 cache or system memory.

In at least one embodiment, inference and/or training logic 515 may include, without limitation, one or more arithmetic logic unit(s) (“ALU(s)”) 510 to perform logical and/or mathematical operations based, at least in part on, or indicated by, training and/or inference code, result of which may result in activations (e.g., output values from layers or neurons within a neural network) stored in an activation storage 520 that are functions of input/output and/or weight parameter data stored in data storage 501 and/or data storage 505. In at least one embodiment, activations stored in activation storage 520 are generated according to linear algebraic and or matrix-based mathematics performed by ALU(s) 510 in response to performing instructions or other code, wherein weight values stored in data storage 505 and/or data 501 are used as operands along with other values, such as bias values, gradient information, momentum values, or other parameters or hyperparameters, any or all of which may be stored in data storage 505 or data storage 501 or another storage on or off-chip. In at least one embodiment, ALU(s) 510 are included within one or more processors or other hardware logic devices or circuits, whereas in another embodiment, ALU(s) 510 may be external to a processor or other hardware logic device or circuit that uses them (e.g., a co-processor). In at least one embodiment, ALUs 510 may be included within a processor's execution units or otherwise within a bank of ALUs accessible by a processor's execution units either within same processor or distributed between different processors of different types (e.g., central processing units, graphics processing units, fixed function units, etc.). In at least one embodiment, data storage 501, data storage 505, and activation storage 520 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 520 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 520 may be cache memory, DRAM, SRAM, non-volatile memory (e.g., Flash memory), or other storage. In at least one embodiment, activation storage 520 may be completely or partially within or external to one or more processors or other logical circuits. In at least one embodiment, choice of whether activation storage 520 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 515 illustrated in FIG. 5A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 515 illustrated in FIG. 5A may be used in conjunction with central processing unit (“CPU”) hardware, graphics processing unit (“GPU”) hardware or other hardware, such as field programmable gate arrays (“FPGAs”).

FIG. 5B illustrates inference and/or training logic 515, according to at least one embodiment. In at least one embodiment, inference and/or training logic 515 may include, without limitation, hardware logic in which computational resources are dedicated or otherwise exclusively used in conjunction with weight values or other information corresponding to one or more layers of neurons within a neural network. In at least one embodiment, inference and/or training logic 515 illustrated in FIG. 5B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 515 illustrated in FIG. 5B may be used in conjunction with central processing unit (CPU) hardware, graphics processing unit (GPU) hardware or other hardware, such as field programmable gate arrays (FPGAs). In at least one embodiment, inference and/or training logic 515 includes, without limitation, data storage 501 and data storage 505, which may be used to store weight values and/or other information, including bias values, gradient information, momentum values, and/or other parameter or hyperparameter information. In at least one embodiment illustrated in FIG. 5B, each of data storage 501 and data storage 505 is associated with a dedicated computational resource, such as computational hardware 502 and computational hardware 506, respectively. In at least one embodiment, each of computational hardware 506 comprises one or more ALUs that perform mathematical functions, such as linear algebraic functions, only on information stored in data storage 501 and data storage 505, respectively, result of which is stored in activation storage 520.

In at least one embodiment, each of data storage 501 and 505 and corresponding computational hardware 502 and 506, respectively, correspond to different layers of a neural network, such that resulting activation from one “storage/computational pair 501/502” of data storage 501 and computational hardware 502 is provided as an input to next “storage/computational pair 505/506” of data storage 505 and computational hardware 506, in order to mirror conceptual organization of a neural network. In at least one embodiment, each of storage/computational pairs 501/502 and 505/506 may correspond to more than one neural network layer. In at least one embodiment, additional storage/computation pairs (not shown) subsequent to or in parallel with storage computation pairs 501/502 and 505/506 may be included in inference and/or training logic 515.

### Neural Network Training and Deployment

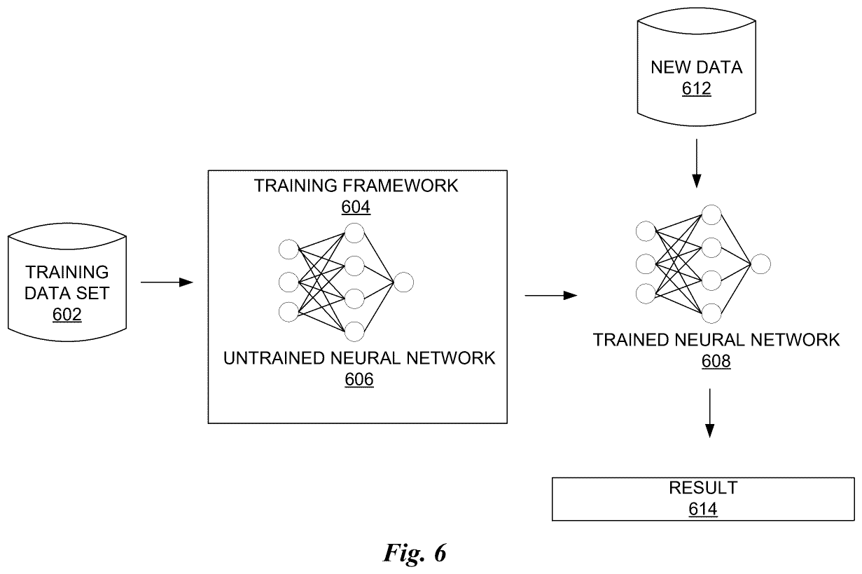

FIG. 6 illustrates another embodiment for training and deployment of a deep neural network. In at least one embodiment, untrained neural network 606 is trained using a training dataset 602. In at least one embodiment, training framework 604 is a PyTorch framework, whereas in other embodiments, training framework 604 is a Tensorflow, Boost, Caffe, Microsoft Cognitive Toolkit/CNTK, MXNet, Chainer, Keras, Deeplearning4j, or other training framework. In at least one embodiment training framework 604 trains an untrained neural network 606 and enables it to be trained using processing resources described herein to generate a trained neural network 608. In at least one embodiment, weights may be chosen randomly or by pre-training using a deep belief network. In at least one embodiment, training may be performed in either a supervised, partially supervised, or unsupervised manner.

In at least one embodiment, untrained neural network 606 is trained using supervised learning, wherein training dataset 602 includes an input paired with a desired output for an input, or where training dataset 602 includes input having known output and the output of the neural network is manually graded. In at least one embodiment, untrained neural network 606 is trained in a supervised manner processes inputs from training dataset 602 and compares resulting outputs against a set of expected or desired outputs. In at least one embodiment, errors are then propagated back through untrained neural network 606. In at least one embodiment, training framework 604 adjusts weights that control untrained neural network 606. In at least one embodiment, training framework 604 includes tools to monitor how well untrained neural network 606 is converging towards a model, such as trained neural network 608, suitable to generating correct answers, such as in result 614, based on known input data, such as new data 612. In at least one embodiment, training framework 604 trains untrained neural network 606 repeatedly while adjust weights to refine an output of untrained neural network 606 using a loss function and adjustment algorithm, such as stochastic gradient descent. In at least one embodiment, training framework 604 trains untrained neural network 606 until untrained neural network 606 achieves a desired accuracy. In at least one embodiment, trained neural network 608 can then be deployed to implement any number of machine learning operations.

In at least one embodiment, untrained neural network 606 is trained using unsupervised learning, wherein untrained neural network 606 attempts to train itself using unlabeled data. In at least one embodiment, unsupervised learning training dataset 602 will include input data without any associated output data or “ground truth” data. In at least one embodiment, untrained neural network 606 can learn groupings within training dataset 602 and can determine how individual inputs are related to untrained dataset 602. In at least one embodiment, unsupervised training can be used to generate a self-organizing map, which is a type of trained neural network 608 capable of performing operations useful in reducing dimensionality of new data 612. In at least one embodiment, unsupervised training can also be used to perform anomaly detection, which allows identification of data points in a new dataset 612 that deviate from normal patterns of new dataset 612.

In at least one embodiment, semi-supervised learning may be used, which is a technique in which in training dataset 602 includes a mix of labeled and unlabeled data. In at least one embodiment, training framework 604 may be used to perform incremental learning, such as through transferred learning techniques. In at least one embodiment, incremental learning enables trained neural network 608 to adapt to new data 612 without forgetting knowledge instilled within network during initial training.

### Data Center

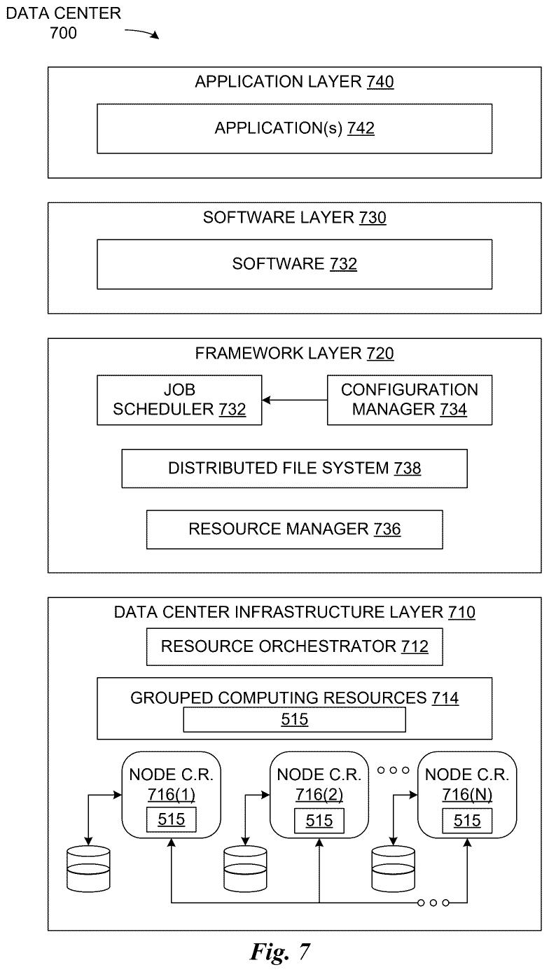

FIG. 7 illustrates an example data center 700, in which at least one embodiment may be used. In at least one embodiment, data center 700 includes a data center infrastructure layer 710, a framework layer 720, a software layer 730 and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 722 may configure or otherwise control one or more node C.R.s 716(1)-716(N) and/or grouped computing resources 714. In at least one embodiment, resource orchestrator 722 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 732, a configuration manager 734, a resource manager 736 and a distributed file system 738. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 738 for large-scale data processing (e.g., “big data”). In at least one embodiment, job scheduler 732 may include a Spark driver to facilitate scheduling of workloads supported by various layers of data center 700. In at least one embodiment, configuration manager 734 may be capable of configuring different layers such as software layer 730 and framework layer 720 including Spark and distributed file system 738 for supporting large-scale data processing. In at least one embodiment, resource manager 736 may be capable of managing clustered or grouped computing resources mapped to or allocated for support of distributed file system 738 and job scheduler 732. In at least one embodiment, clustered or grouped computing resources may include grouped computing resource 714 at data center infrastructure layer 710. In at least one embodiment, resource manager 736 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 738 of framework layer 720. one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 738 of framework layer 720. one or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 734, resource manager 736, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underutilized and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 515 are used to perform inferencing and/or training operations associated with one or more embodiments. In at least one embodiment, inference and/or training logic 515 may be used in system FIG. 7 for inferencing or predicting operations based, at least in part, on weight parameters calculated using neural network training operations, neural network functions and/or architectures, or neural network use cases described herein.

As described herein, a method, computer readable medium, and system are disclosed to provide vector-space representations of library cells. In accordance with FIGS. 1-4, embodiments may provide a models usable for performing inferencing operations and for providing inferenced data (e.g. the learned representations). The models may be stored (partially or wholly) in one or both of data storage 501 and 505 in inference and/or training logic 515 as depicted in FIGS. 5A and 5B. Training and deployment of the models may be performed as depicted in FIG. 6 and described herein. Distribution of the models may be performed using one or more servers in a data center 700 as depicted in FIG. 7 and described herein.

What is claimed is:

1. A method, comprising:
at a device:
accessing a preconfigured circuit design comprised of a plurality of library cells;
learning a vector space representation of one or more library cells of the plurality of library cells, the vector space representation for each library cell of the one or more library cells being a learned encoding of dynamic properties of the library cell; and
processing the vector space representation of the one or more library cells, by a machine learning model, to generate a new circuit design that is more optimal than the preconfigured circuit design.

2. The method of claim 1, wherein the dynamic properties include functional characteristics of the library cell and electrical characteristics of the library cell.

3. The method of claim 1, wherein the dynamic properties of the library cell are predefined in a set of text-based files.

4. The method of claim 1, wherein the vector space representation of the library cell is learned such that the vector space representation maximizes accuracy on one or more preconfigured regularity tests.

5. The method of claim 4, wherein the one or more preconfigured regularity tests include one or more of:
at least one inverting functionality test that evaluates whether the vector space representation captures an inverting functionality relationship existing in the preconfigured circuit design,
at least one functional similarity test that evaluates whether the vector space representation captures a functional similarity existing in the preconfigured circuit design, or
at least one electrical similarity test that evaluates whether the vector space representation captures a delay-specific similarity relationship existing in the preconfigured circuit design.

6. The method of claim 1, wherein the vector space representation is learned using an attention-based machine learning model architecture.

7. The method of claim 6, wherein the attention-based machine learning model architecture includes components trained with self-supervision using a set of files describing functional and electrical properties of library cells.

8. The method of claim 7, wherein the attention-based machine learning model architecture includes a first model that learns a functional output prediction for the vector space representation a second model that learns an electrical output prediction for the vector space representation.

9. The method of claim 8, wherein the functional output prediction is learned by:
generating a functional embedding for an output pin by attending to a functional embedding of the library cell and embeddings of all corresponding pins, and
transforming the functional embedding of the output pin into a logic value prediction representing the functional output prediction.

10. The method of claim 8, wherein the electrical prediction is learned by:
concatenating a base electrical embedding of the library cell with a property token embedding to form a concatenated embedding,
combining the concatenated embedding with input and output pin embeddings to create a timing arc embedding, and
mapping the timing arc embedding to the electrical output prediction.

11. A method, comprising:
at a device:
learning a vector space representation of a library cell of a circuit design; and
outputting the vector space representation of the library cell.

12. The method of claim 11, wherein the vector space representation is learned to encode properties of the library cell.

13. The method of claim 12, wherein the properties include dynamic properties.

14. The method of claim 13, wherein the dynamic properties include functional characteristics of the library cell and electrical characteristics of the library cell.

15. The method of claim 12, wherein the properties of the library cell are predefined in a set of text-based files.

16. The method of claim 11, wherein the vector space representation of the library cell is learned such that the vector space representation maximizes accuracy on one or more preconfigured regularity tests.

17. The method of claim 16, wherein the one or more preconfigured regularity tests include at least one inverting functionality test that evaluates whether the vector space representation captures an inverting functionality relationship existing in the circuit design.

18. The method of claim 16, wherein the one or more preconfigured regularity tests include at least one functional similarity test that evaluates whether the vector space representation captures a functional similarity existing in the circuit design.

19. The method of claim 16, wherein the one or more preconfigured regularity tests include at least one electrical similarity test that evaluates whether the vector space representation captures a delay-specific similarity relationship existing in the circuit design.

20. The method of claim 11, wherein the vector space representation is learned using an attention-based machine learning model architecture.

21. The method of claim 20, wherein the attention-based machine learning model architecture includes components trained with self-supervision using a set of files describing functional and electrical properties of library cells.

22. The method of claim 20, wherein the attention-based machine learning model architecture includes a first model that learns a functional output prediction for the vector space representation a second model that learns an electrical output prediction for the vector space representation.

23. The method of claim 22, wherein the functional output prediction is learned by:
generating a functional embedding for an output pin by attending to a functional embedding of the library cell and embeddings of all corresponding pins, and
transforming the functional embedding of the output pin into a logic value prediction representing the functional output prediction.

24. The method of claim 22, wherein the electrical prediction is learned by:
concatenating a base electrical embedding of the library cell with a property token embedding to form a concatenated embedding,
combining the concatenated embedding with input and output pin embeddings to create a timing arc embedding, and
mapping the timing arc embedding to the electrical output prediction.

25. The method of claim 11, wherein vector space representations of a plurality of library cells of the circuit design are learned.

26. The method of claim 11, wherein the vector space representation of the library cell is output to a downstream application.

27. The method of claim 26, wherein the downstream application includes a machine learning model that optimizes the circuit design based on the vector space representation of the library cell.

28. The method of claim 26, wherein the downstream application includes a machine learning model that predicts an output vector at an output pin of the library cell using the vector space representation of the library cell.

29. The method of claim 26, wherein the downstream application includes a machine learning model that predicts a logic probability for an output of the library cell using the vector space representation of the library cell.

30. The method of claim 26, wherein the downstream application includes a machine learning model that predicts switching activity of the library cell using the vector space representation of the library cell.

31. A system, comprising:
a non-transitory memory storage comprising instructions; and
one or more processors in communication with the memory, wherein the one or more processors execute the instructions to:
learn a vector space representation of a library cell of a circuit design; and
output the vector space representation of the library cell.

32. The system of claim 31, wherein the vector space representation is learned to encode properties of the library cell.

33. The system of claim 31, wherein the vector space representation of the library cell is output to a downstream application to cause a machine learning model of the downstream application to:
optimize the circuit design based on the vector space representation of the library cell,
predict an output vector at an output pin of the library cell using the vector space representation of the library cell,
predict a logic probability for an output of the library cell using the vector space representation of the library cell, or
predict switching activity of the library cell using the vector space representation of the library cell.

34. A non-transitory computer-readable media storing computer instructions which when executed by one or more processors of a device cause the device to:
learn a vector space representation of a library cell of a circuit design; and
output the vector space representation of the library cell.

35. The non-transitory computer-readable media of claim 34, wherein the vector space representation is learned to encode properties of the library cell.

36. The non-transitory computer-readable media of claim 34, wherein the vector space representation of the library cell is output to a downstream application to cause a machine learning model of the downstream application to:
optimize the circuit design based on the vector space representation of the library cell,
predict an output vector at an output pin of the library cell using the vector space representation of the library cell,
predict a logic probability for an output of the library cell using the vector space representation of the library cell, or
predict switching activity of the library cell using the vector space representation of the library cell.
